(19) United States
(12) Patent Application Publication
(10) Pub. No.: US 2011/0299258 A1
(43) Pub. Date: Dec. 8, 2011

(54) MOUNT STRUCTURE FOR ELECTRICAL BOARD, AND IMAGE FORMING APPARATUS HAVING THE SAME

(75) Inventor: Takeshi ISHII, Osaka (JP)

(73) Assignee: KYOCERA MITA CORPORATION, Osaka (JP)

(21) Appl. No.: 13/118,968

(22) Filed: May 31, 2011

(30) Foreign Application Priority Data
Jun. 2, 2010 (JP) 2010-126396

(51) Int. Cl. H05K 5/04

(52) U.S. Cl. 361/752

(57) ABSTRACT

A mount structure includes: a plurality of metal frames over which the respective electrical boards disposing an electronic component are removably mounted; stacks and mounts the frames. An uppermost frame is an N-th frame (N is an integer of 2 or larger) and a frame disposed under the N-th frame is an (N−1)-th frame. A metal cover case that houses an N-th electrical board which is mounted over the N-th frame and is removably mounted on the N-th frame is provided; wherein the N-th frame is removably mounted over the (N−1)-th frame at an N-th mount portion such that the N-th frame faces an (N−1)-th electrical board that is mounted over the (N−1)-th frame; and the N-th mount portion is disposed at an outer portion with respect to the cover case that is mounted on the N-th frame.

This application is based on Japanese Patent Application No. 2010-126396 filed on Jun. 2, 2010, the contents of which are hereby incorporated by reference.

### BACKGROUND OF THE INVENTION

1. Field of the Invention

The present invention relates to a mount structure for an electrical board that removably mounts a plurality of electrical boards on which an electronic component is disposed; and to an image forming apparatus that includes the mount structure.

2. Description of the Related Art

Conventionally, image forming apparatuses such as a copy machine, a printer, a facsimile apparatus and the like are provided with a control portion for executing an image forming process and operating a drive member that is used for the execution. The control portion uses an electrical board on which a circuit including various electronic components such as an IC and the like is formed and the electrical board is mounted on a frame.

For example, in a first related art, an electrical board for mechanical control and an electrical board for image processing are mounted next to each other on a frame; an electrical board for an interface of an external apparatus is connected to the electrical board for mechanical control; and the boards are covered by a cover case. On the other hand, an interface board for external connection and a hard disc unit for storing image data are connected to the electrical board for image processing; the board, the interface board and the like are covered by another cover case.

However, in the first related art, the two electrical boards are mounted next to each other on the frame, so that if the above frame is mounted on one surface that constitutes an apparatus main body of an image forming apparatus, the frame occupies a large area of the constituent surface of the apparatus main body and limits the degree of freedom for mounting another constituent member on the surface, and the apparatus becomes large, which are problems.

### SUMMARY OF THE INVENTION

It is an object of the present invention to allow a plurality of electrical boards to be mounted without occupying a large area and without detriment to the respective characteristics of the electrical boards; further, to facilitate replacement of the electrical boards in maintenance working and assembly working.

A mount structure for an electrical board according to an aspect of the present invention includes: electric boards on which an electronic component is disposed; and metal frames over which the electrical board are removably mounted; the frames are stacked and mounted, the mount structure includes:

when an uppermost frame is an N-th frame and a frame disposed under the N-th frame is an (N−1)-th frame (N is an integer of 2 or larger),

a metal cover case that houses an N-th electrical board which is mounted over the N-th frame and is removably mounted over the N-th frame;

wherein the N-th frame is removably mounted over the (N−1)-th frame at an N-th mount portion such that the N-th frame faces an (N−1)-th electrical board that is mounted over the (N−1)-th frame; and

the N-th mount portion is disposed at an outer portion with respect to the cover case that is mounted on the N-th frame.

Other objects of the present invention and specific advantages obtained by the present invention are will be more apparent from description of embodiments described hereinafter.

### DESCRIPTION OF THE DRAWINGS

FIG. 1 is a view showing a schematic structure of an image forming apparatus that includes a mount structure for an electrical board according to a first embodiment of the present invention.

FIG. 2 is a perspective view showing the image forming apparatus that includes the mount structure for an electrical board according to the first embodiment of the present invention.

FIG. 3 is a perspective view showing the mount structure for an electrical board with a cover case removed according to the first embodiment of the present invention.

FIG. 4 is a perspective view showing the mount structure for an electrical board with a second frame removed according to the first embodiment of the present invention.

FIG. 5 is a sectional view schematically showing the mount structure for an electrical board according to the first embodiment of the present invention.

FIG. 6 is a sectional view schematically showing a mount structure for an electrical board according to a second embodiment of the present invention.

### DESCRIPTION OF PREFERRED EMBODIMENTS

Hereinafter, embodiments of the present invention are described with reference to the drawings; however, the present invention is not limited to the embodiments. Besides, applications and terms and the like described here are not limited to the embodiments.

### First Embodiment

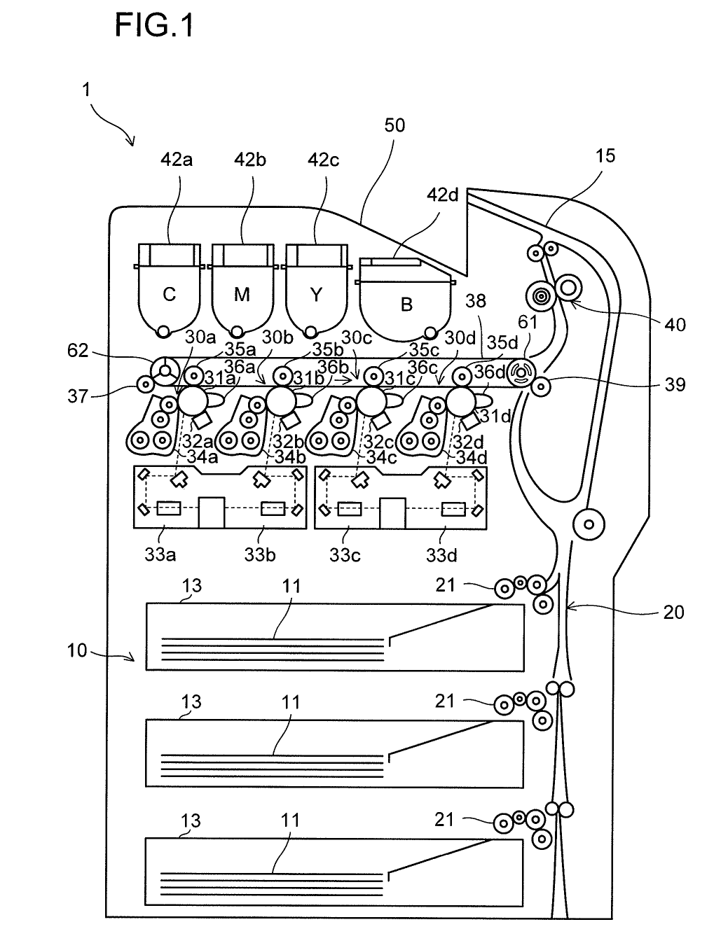

FIG. 1 is a view schematically showing a tandem type of color copy machine that is an embodiment of an image forming apparatus according to the present invention. An image forming apparatus 1 includes: a paper-sheet supply portion 10 that stores paper sheets 11; four exposure units 33a to 33d that are disposed over the paper-sheet supply portion 10; image forming portions 30a to 30d that are disposed over the exposure units 33a to 33d; a fixing portion 40 that is disposed at an upper right position above the image forming portions 30a to 30d; a paper-sheet carry portion 20 that is disposed to the right of the paper-sheet supply portion 10; and an ejection portion 50 that ejects the paper sheets 11 to an upper position of the image forming apparatus 1.

The paper-sheet supply portion 10 includes a plurality of paper-sheet supply cassettes 13 that store the paper sheets 11; in response to rotation of a paper-sheet supply roller 21, sends out the paper sheets 11 one after another from one paper-sheet supply cassette 13 selected from the plurality of paper-sheet supply cassettes 13 to the paper-sheet carry portion 20. The paper-sheet carry portion 20 includes: a pair of carry rollers; a carry guide and the like; carries the paper sheets 11 sent out from the paper-sheet cassette 13 to the image forming portions 30a to 30d.

The image forming portions 30a to 30d are disposed corresponding to the respective colors of cyan, magenta, yellow, and black. The image forming portions 30a to 30d includes photoreceptors 31a to 31d; around the photoreceptors 31a to 31d and in order from upstream sides in rotation directions of the photoreceptors 31a to 31d, electrifiers 32a to 32d, development apparatuses 34a to 34d, transfer rollers 35a to 35d, and cleaners 36a to 36d are disposed.

The photoreceptors 31a to 31d use an amorphous silicon photoreceptor as a photosensitive material to form a photosensitive layer. Here, the photosensitive layer may be formed of an organic photoreceptor (OPC photoreceptor). The development apparatuses 34a to 34d are disposed to the left of the photoreceptors 31a to 31d and supply toners to the photoreceptors 31a to 31d; the electrifiers 32a to 32d evenly electrify surfaces of the photoreceptors 31a to 31d. On a downstream side in the rotation directions of the photoreceptors with respect to the development apparatuses 34a to 34d, not-shown electricity removers are so disposed as to face the surfaces of the photoreceptors 31a to 31d and remove electric charges remaining on the surfaces of the photoreceptors 31a to 31d after development.

The exposure units 33a to 33d, based on document image data input from an external apparatus (not shown), shine laser light onto the surfaces of the photoreceptors 31a to 31d as represented by broken lines; and are disposed under the development apparatuses 34a to 34d. The exposure units 33a to 33d are provided with: a laser light source; a polygonal mirror; a reflection mirror; and a lens. The laser light emitted from the laser light sources is shined onto the surfaces of the photoreceptors 31a to 31d from a downstream side in the rotation directions of the photoreceptors with respect to the electrifiers 32a to 32d. By the laser light shined from the exposure units 33a to 33d, electrostatic latent images are formed on the respective surfaces of the photoreceptors 31a to 31d; these electrostatic latent images are developed into toner images by the respective development apparatuses 34a to 34d.

When toners in the development apparatuses 34a to 34d are consumed, toners having the respective colors of cyan, magenta, yellow, and black are supplied from toner cartridges 42a to 42d disposed over the image forming portions 301 to 30d to the development apparatuses 34a to 34d.

An endless intermediate transfer belt 38 is mounted between a drive roller 61 and a driven roller 62. Under this intermediate transfer belt 38, the photoreceptors 31a to 31d are disposed next to each other along a carry direction (arrow direction in FIG. 1), face to come into contact with the intermediate transfer belt 38. Each of primary transfer rollers 35a to 35d faces each of the photoreceptors 31a to 31d via the intermediate transfer belt 38 and is so disposed as to come into contact with the intermediate transfer belt 38. Besides, each of the primary transfer rollers 35a to 35d is movable in a vertical direction, comes into tight contact with each of the photoreceptors 31a to 31d via the intermediate transfer belt 38 to form a primary transfer nip portion if necessary, and goes off. At this primary transfer nip portion, in response to the rotation of the intermediate transfer belt 38, the respective toner images on the photoreceptors 31a to 31d are successively transferred to the intermediate transfer belt 38 at predetermined timing. In this way, a toner image with the four-color toner images of cyan, magenta, yellow and black overlapped with each other is formed on the surface of the intermediate transfer belt 38.

A secondary transfer roller 39 faces the drive roller 61 via the intermediate transfer belt 38 and comes into tight contact with the intermediate transfer belt 38. The tight-contact portion between the secondary transfer roller 39 and the intermediate transfer belt 38 forms a secondary transfer nip portion; at this secondary transfer nip portion, the toner image on the surface of the intermediate transfer belt 38 is transferred to the paper sheet 11. A belt cleaning 37, after the transfer, sweeps away toners remaining on the intermediate transfer belt 38.

The fixing portion 40 heats and pressurizes the paper sheet 11 on which the toner image is transferred by the image forming portions 30a to 30d to melt and fix the toner image on the paper sheet 11. The paper sheet 11 that passes the fixing portion 40 is ejected to the ejection portion 50 via the paper-sheet carry path 15.

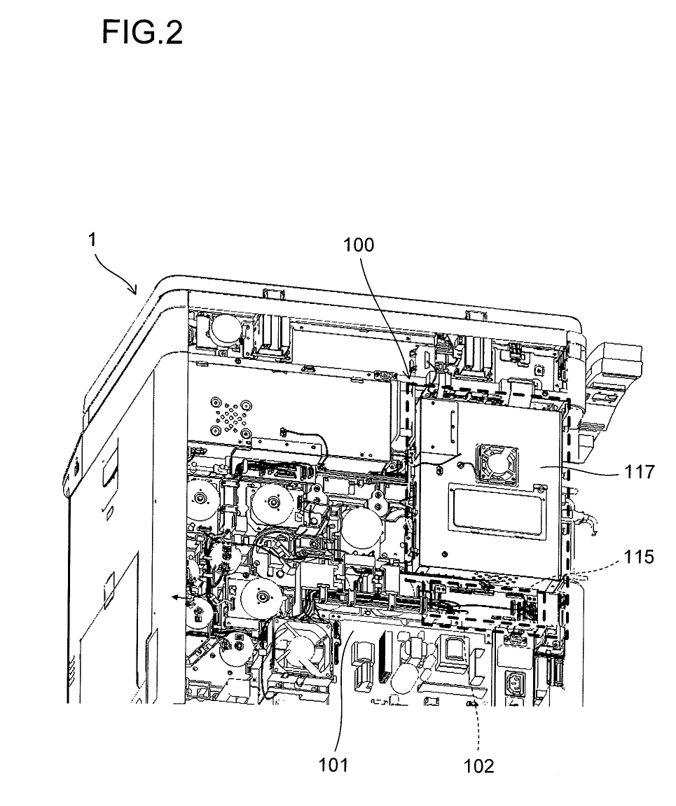

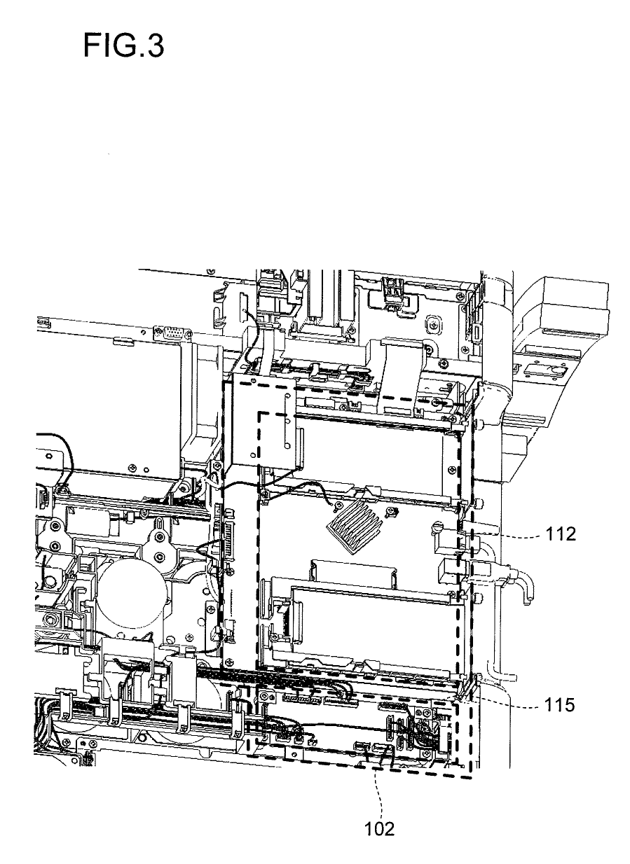

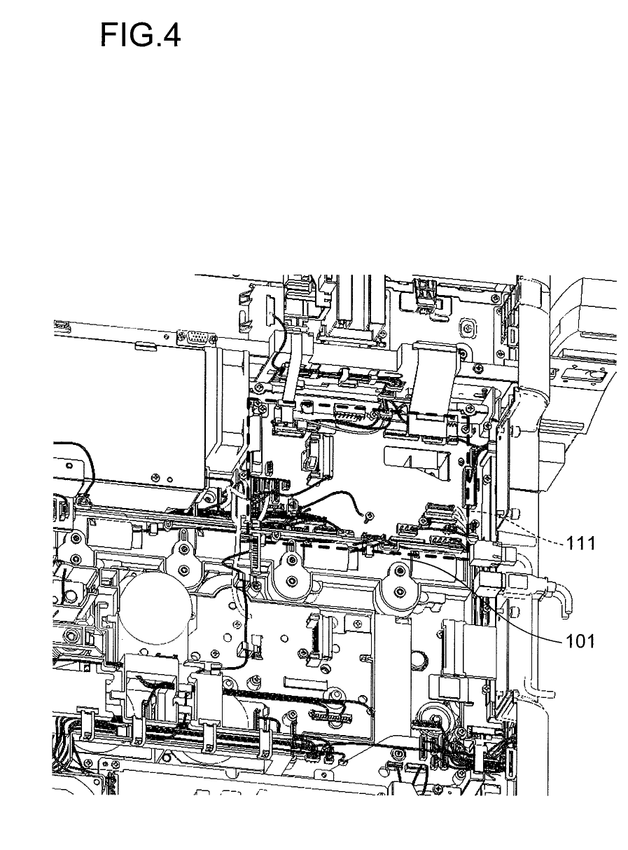

FIG. 2 is a perspective view showing a rear side of the above image forming apparatus and shows a mount structure 100 for an electrical board according to the present invention with an outer panel on the rear side of the apparatus removed. Besides, FIG. 3 shows the mount structure 100 for an electrical board with a cover case removed; further, FIG. 4 is a perspective view showing the mount structure 100 for an electrical board with a second frame removed. Here, in FIGS. 2 to 4, an electrical board and a frame that constitute the mount structure 100 for an electrical board are represented by broken lines.

The mount structure 100 for an electrical board is composed by stacking the frame and the electrical board and includes: a rear frame 101 (see FIG. 2, FIG. 4) that is a first frame; a second frame 102 (see FIG. 2, FIG. 3); an engine board 111 (see FIG. 4) that is a first electrical board; a controller board 112 (see FIG. 3) that is a second electrical board; a sub-electrical board 115 (see FIG. 2, FIG. 3); and a cover case 117 (see FIG. 2).

The rear frame 101 is formed of a metal plate made of a metal such as iron or the like and constitutes the apparatus main body of the image forming apparatus 1; on the rear frame 101, together with various constituent members of the apparatus, the engine board 111 is mounted (see FIG. 4).

The engine board 111 is a circuit board which includes electronic components for performing drive control of the image forming portion and on which electronic components that are likely to erroneously operate under influence of electromagnetic waves are disposed.

As shown in FIG. 3, the second frame is formed of substantially a rectangular metal plate made of a metal such as iron or the like and is so mounted over the rear frame 101 as to cover the engine board 111. Over an upper surface of the second frame 102, the controller board 112 that has a relatively large flat area and the sub-electrical board 115 that has a relatively small flat area are mounted next to each other.

The controller board 112 is a circuit board that includes electronic components such as a process computer, a storage device and the like which receive information about image formation and paper-sheet carry; process the information and output the processed information; and is electrically connected to the engine board 111 by a not-shown flat cable. This controller board 112 is more likely to erroneously operate than the engine board 111 under influence of electromagnetic waves.

The sub-electrical board 115 is a circuit board that includes a not-shown external connector terminal; and by means of this external connector terminal, allows replacement of drive control software of the image forming portion and addition of a function and the like which the image forming apparatus 1 does not include originally. For example, in a case where only a function as a copy machine is provided at a time of shipment; and a facsimile function is added to an image read portion, or in a case where a memory is expanded in accordance with function addition, a circuit board is connected to the sub-electrical board 115. The sub-electrical board 115 is electrically connected to the engine board 111 by a not-shown flat cable; besides, is also connected to the controller board 112; and external information is transmitted to the engine board 111 and the controller board 112 via the sub-electrical board 115.

As shown in FIG. 2, the sub-electrical board 115 is exposed over the second frame 102; however, the controller board 112 is housed in the cover case 117.

The cover case 117 is formed of a metal plate made of a metal such as iron or the like into a rectangular box shape with one surface opened; and is mounted on the upper surface of the second frame 102 with the controller board 112 housed in the inside.

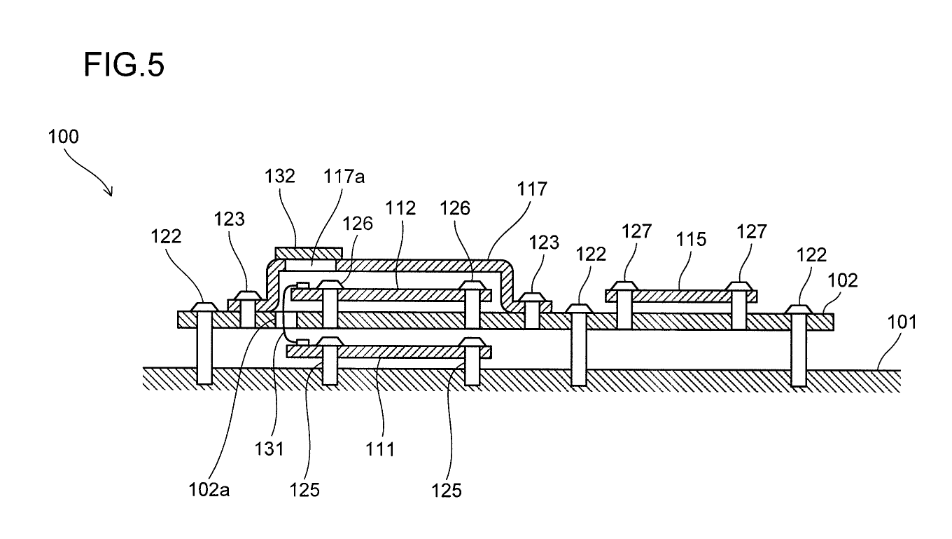

Next, dispositions and mount structures of the boards 111, 112, 115, the second frame 102 and the cover case 117 are described in detail based on FIG. 5. FIG. 5 is a sectional view schematically showing the mount structure 100 for an electrical board.

The engine board 111 is removably mounted over the rear frame 101 by a plurality of board screws 125 with a gap formed on the rear frame 101. Here, a not-shown gap washer is interposed between the rear frame 101 and the engine board 111; the engine board 111 forms a predetermined gap by means of the gap washer with respect to the rear frame 101. The other boards 112, 115 also likewise form a predetermined gap by means of a gap washer.

The second frame 102 is so disposed as to face an upper surface of the engine board 111; and is removably mounted over the rear frame 101 by means of a plurality of second screws 122. A gap washer is applied to the second screw 122 between the second frame 102 and the rear frame 101 to form a predetermined gap such that the engine board 111 and electronic components disposed on the board 111 do not come into contact with the second frame 102.

The sub-electrical board 115 is removably mounted over the second frame 102 by a plurality of board screws 127 with a gap formed on the second frame 102.

Besides, the controller board 112 is removably mounted over the second frame 102 by a plurality of board screws 126 with a gap formed on the second frame 102. The controller board 112 is disposed at a position to face the engine board 111 via the second frame 102.

The controller board 112 is electrically connected to the engine board 111 by a flat cable 131. The flat cable 131 passes through a hole 102a formed through the second frame 102 to extend in a vertical direction and removably connected to respective connectors (not shown) of the controller board 112 and the engine board 111.

The cover case 117 houses the controller board 112 having a space that prevents electronic components disposed on the controller board 112 from coming into contact with the cover case 117. A plurality of case mount screws 123 are disposed at positions not to overlap with the second screws 122; by means of these case mount screws 123, a flange portion of the cover case 117 is removably mounted on the second frame 102.

The cover case 117 is provided with an opening 117a that opens an upper side of the cove case 117; further, a plate-shape lid member 132 is disposed to allow the opening 117a to be freely opened and closed. The lid member 132 is mounted on the cover case 117 by means of a screw (not shown); when the screw is removed, the opening 117a is opened. Here, the lid member 132 may be movably supported by the cover case 117 by means of a hinge. The opening 117a is disposed near the flat cable 131; by opening the lid member 132, it is possible to remove the flat cable 131 connected to the controller board 112 via the opening 117a.

To replace the controller board 112 in maintenance working and assembly working, the case mount screw 123 is removed from the second frame 102; then, the cover case 117 is removed from the second frame 102. Further, the flat cable 131 and a flat cable (not shown) connected to the sub-electrical board 115 are removed from the controller board 112; then, the board screw 126 is removed from the controller board 112. Another controller board 112 is prepared; and in a procedure reverse to the removal working, another controller board 112 is mounted over the second frame 102; the flat cable is connected; finally, the cover case 117 is mounted on the second frame 102.

Next, to replace the engine board 11, first of all, a flat cable (not shown) that connects the engine board 11 to the electrical board 115 is removed from the sub-electrical board 115. Then, the lid member 132 on the cover case 117 is opened; via the opening 117a, the flat cable 131 connected to the engine board 111 is removed from the controller board 112. Then, the second screw 122 is removed from the rear frame 101; then, the second frame 102 over which the controller board 112 and the sub-electrical board 115 are mounted is removed from the rear frame 101. Then, the flat cable 131 is removed from the engine board 111, and the board screw 125 is removed from the engine board 111. Another engine board 111 is prepared; in a procedure reverse to the removal working, another engine board 111 is mounted over the rear frame 101; the flat cable 131 is connected to the engine board 111; finally, the second frame 102 is mounted over the rear frame 101.

Next, to replace the drive control software and the like of the image forming portion or to add a function that the image forming apparatus 1 does not include, drive control software for the replacement is input from the external connector terminal (not shown) of the sub-electrical board 115; besides, in accordance with the function addition, a circuit board for the expansion is connected to the external connector terminal (not shown) and predetermined working is performed, so that the function change and addition for the engine board 111 and controller board 112 that are connected to the sub-electrical board 115 are performed.

### Second Embodiment

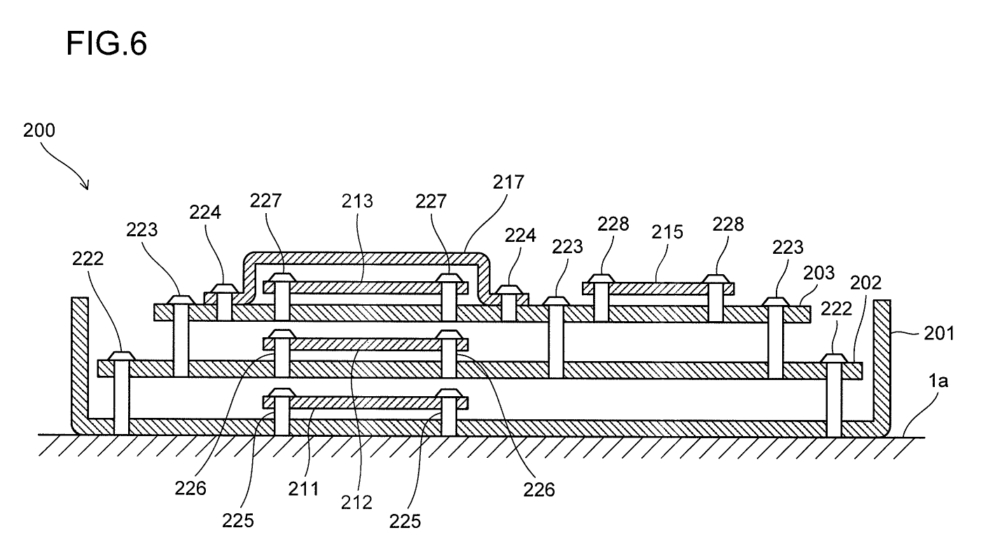

FIG. 6 is a sectional view schematically showing a mount structure for an electrical board according to a second embodiment. The second embodiment employs a structure that stacks three frames; a structure different from the first embodiment is chiefly described hereinafter; and description of the same portions as the first embodiment is skipped.

A mount structure 200 for an electrical board is mounted on the apparatus main body 1a of the image forming apparatus 1; and includes: a bottom frame 201 that is the first frame; a second frame 202; a third frame 203; a first electrical board 211; a second electrical board 211; a third electrical board 213; a sub-electrical board 215; and a cover case 217.

The bottom frame 201 is formed of a metal plate made of a metal such as iron or the like into a rectangular box shape with an upper side opened; in the box, the second frame 202 and the third frame 203 are housed. Besides, the bottom frame 201 is removably mounted on the apparatus main body 1a of the image forming apparatus 1 by means of a not-shown screw.

The first electrical board 211 is a circuit board which includes electronic components for performing drive control of the image forming portion and on which electronic components that are likely to erroneously operate under influence of electromagnetic waves are disposed. Besides, the first electrical board 211 is removably mounted over the bottom frame 201 by a plurality of board screws 225 with a gap formed on the bottom frame 201. Here, a not-shown gap washer is interposed between the bottom frame 201 and the first electrical board 211; the first electrical board 211 forms a predetermined gap by means of the gap washer with respect to the bottom frame 201. The other boards 212, 213, 215 also likewise form a predetermined gap by means of a gap washer.

The second frame 202 is formed of a metal plate made of a metal such as iron or the like into substantially a rectangular shape; and is so disposed in the bottom frame 201 as to face an upper surface of the first electrical board 211. Besides, the second frame 202 is removably mounted over the bottom frame 201 by means of a plurality of second screws 222. A gap washer is applied to the second screw 222 between the second frame 202 and the bottom frame 201 to form a predetermined gap such that the first electrical board 211 and electronic components disposed on the board 211 do not come into contact with the second frame 202.

The second electrical board 212 is removably mounted over the second frame 202 by a plurality of board screws 226 with a gap formed on an upper surface of the second frame 202. The second electrical board 212 is disposed at a position to face the first electrical board 211 via the second frame 102.

The second electrical board 212, like the first electrical board 211, is a circuit board which includes electronic components for performing drive control of the image forming portion and on which electronic components that are likely to erroneously operate under influence of electromagnetic waves are disposed.

The third frame 203 is formed of a metal plate made of a metal such as iron or the like into substantially a rectangular shape; and is so disposed in the bottom frame 201 as to face an upper surface of the second electrical board 212. Besides, the third frame 203 is removably mounted over the second frame 202 by means of a plurality of third screws 223. Here, a predetermined gap is formed between the third frame 203 and the second frame 202 such that the second electrical board 212 and electronic components disposed on the board 212 do not come into contact with the third frame 203.

The flat surface area (area in a direction perpendicular to the paper surface of FIG. 6) of the third frame 203 is smaller than the flat surface area of the second frame 202; further, the end surfaces of the third frame 203 are so disposed as to be situated at inner positions with respect to the positions where the plurality of second screws 222 are disposed. In other words, the plurality of second screws 222 for mounting the second frame 202 are disposed at outer positions with respect to the mount positions where the plurality of third screws 223 for mounting the third frame 203 are disposed on the second frame 202.

Over an upper surface of the third frame 203, the sub-electrical board 215 and the third electrical board 213 are disposed next to each other. The sub-electrical board 215 is removably mounted over the third frame 203 by a plurality of board screws 228 with a gap formed on the third frame 203; besides, the third electrical board 213 is removably mounted over the third frame 203 by the plurality of board screws 228 with a gap formed on the third frame 203. The third electrical board 213 is disposed at a position to face the second electrical board 212 via the third frame 203.

The third electrical board 213 is a circuit board that includes electronic components such as a process computer, a storage device and the like which receive information about image formation and paper-sheet carry; process the information and output the processed information for drive control; and is electrically connected to the second electrical board 212 by a not-shown flat cable. This third electrical board 213 is more likely to erroneously operate than the first and second electrical boards 211, 212 under influence of electromagnetic waves.

The sub-electrical board 215 is a circuit board that includes a not-shown external connector terminal; and by means of this external connector terminal, allows replacement of the drive control software of the image forming portion and addition of a function which the image forming apparatus 1 does not include originally. For example, in a case where only a function as a copy machine is provided at a time of shipment; and a facsimile function is added to the image read portion, or in a case where a memory is expanded in accordance with function addition, a circuit board is connected to the sub-electrical board 215. The sub-electrical board 215 is electrically connected to the first to third electrical boards 211 to 213 by a not-shown flat cable; and external information is transmitted to the first to third electrical boards 211 to 213 via the sub-electrical board 215.

The first to third electrical boards 211 to 213 have relatively a large flat surface area, while the sub-electrical board 215 has a small surface area compared with the first to third electrical boards 211 to 213.

The cover case 217 is formed of a metal plate made of a metal such as iron or the like into a rectangular box shape; and houses the third electrical board 213 having a space that prevents the electronic components disposed on the third electrical board 213 from coming into contact with the cover case 217. A plurality of case mount screws 224 are disposed at positions not to overlap with the third screws 223; by means of these case mount screws 224, a flange portion of the cover case 217 is removably mounted on the third frame 203.

To replace the third electrical board 213 in maintenance working and assembly working, the case mount screw 224 is removed from the third frame 203; then, the cover case 217 is removed from the third frame 203. Further, a flat cable (not shown) is removed from the third electrical board 213; then, the board screw 227 is removed from the third electrical board 213. Another third electrical board 213 is prepared; and in a procedure reverse to the removal working, another third electrical board 213 is mounted over the third frame 203; the flat cable (not shown) is connected; finally, the cover case 217 is mounted on the third frame 203.

Next, to replace the second electrical board 212, first of all, the third screw 223 is removed from the third frame 203; then, the third frame 203 over which the third electrical board 213 and the sub-electrical board 215 are mounted is removed from the second frame 202. Then, a flat cable (not shown) connected to the second electrical board 212 is removed; and the board screw 226 is removed from the second electrical board 212. Another second electrical board 212 is prepared; in a procedure reverse to the removal working, another second electrical board 212 is mounted; a flat cable (not shown) is connected to the second electrical board 212; finally, the third frame 203 is mounted over the second frame 202.

Next, to replace the first electrical board 211, first of all, the second screw 222 is removed from the second frame 202; then, the second frame 202 over which the second electrical board 212 and the third frame 203 are mounted is removed from the bottom frame 201. Then, a flat cable (not shown) connected to the first electrical board 211 is removed; and the board screw 225 is removed from the first electrical board 211. Another first electrical board 211 is prepared; in a procedure reverse to the removal working, another first electrical board 211 is mounted over the bottom frame 201; a flat cable (not shown) is connected to the first electrical board 211; finally, the second frame 20 is mounted over the bottom frame 201.

Next, to replace the drive control software and the like of the image forming portion or to add a function that the image forming apparatus 1 does not include, drive control software for the replacement is input from the external connector terminal (not shown) of the sub-electrical board 215; besides, in accordance with the function addition, a circuit board for the expansion is connected to the external connector terminal (not shown) and predetermined working is performed, so that the function change and addition for the first to third electrical boards 211 to 213 that are connected to the sub-electrical board 215 are performed.

Here, in the above first embodiment, the structure which stacks the two frames (N=2) is described; besides, in the second embodiment, the structure which stacks the three frames (N=3) is described; however, the present invention is not limited to these: a structure which stacks four or more frames (N=4 or larger) may be employed. In this case as well, the same effects as in the above embodiments are obtained.

The present invention is applicable to a mount structure for an electrical board that removably mounts a plurality of electrical boards on which an electronic component is disposed; and to an image forming apparatus that includes the mount structure.

What is claimed is:

1. A mount structure for an electrical board comprises: electric boards on which an electronic component is disposed; and metal frames over which the electrical board are removably mounted; the frames are stacked and mounted, the mount structure comprising:
when an uppermost frame is an N-th frame and a frame disposed under the N-th frame is an (N−1)-th frame (N is an integer of 2 or larger),
a metal cover case that houses an N-th electrical board which is mounted over the N-th frame and is removably mounted over the N-th frame;
wherein the N-th frame is removably mounted over the (N−1)-th frame at an N-th mount portion such that the N-th frame faces an (N−1)-th electrical board that is mounted over the (N−1)-th frame; and
the N-th mount portion is disposed at an outer portion with respect to the cover case that is mounted on the N-th frame.

2. The mount structure for an electrical board according to claim 1, wherein
when the frame disposed under the N-th frame is the (N−1)-th frame and a frame disposed under the (N−1)-th frame is an (N−2)-th frame (N is an integer of 3 or larger),
wherein the (N−1)-th frame is removably mounted over the (N−2)-th frame at an (N−1)-th mount portion such that the (N−1)-th frame faces an (N−2)-th electrical board that is mounted over the (N−2)-th frame; and
the (N−1)-th mount portion is disposed at an outer portion with respect to a mount position of the N-th mount portion where the N-th mount portion is mounted over the (N−1)-th frame.

3. The mount structure for an electrical board according to claim 1, further comprising a connection cable that electrically connects the N-th and (N−1)-th electrical boards to each other; wherein the cover case includes a lid member, which is freely opened and closed, at a position near the connection cable.

4. The mount structure for an electrical board according to claim 3, wherein the lid member is so disposed as to be able to freely open and close an upper side of the cover case.

5. The mount structure for an electrical board according to claim 1, further comprising a sub-electrical board that is electrically connected to the (N−1)-th electrical board;
wherein the sub-electrical board is mounted over the N-th frame at a position that does not overlap with the N-th mount portion and at an outer position with respect to the cover case.

6. The mount structure for an electrical board according to claim 5, wherein the sub-electrical board is provided with an external connector terminal.

7. The mount structure for an electrical board according to claim 1, wherein a bottom frame disposed on a lowermost side is formed into a box shape with an upper surface opened; and a frame disposed over a bottom surface of the bottom frame is housed in the bottom frame.

8. The mount structure for an electrical board according to claim 1, wherein the mount portion is composed of a screw.

9. The mount structure for an electrical board according to claim 1, wherein on the N-th electrical board, an electronic component that includes a process computer or a storage device is disposed.

10. The mount structure for an electrical board according to claim 1, wherein the electrical board is mounted over the frame a predetermined gap away from the frame.

11. An image forming apparatus comprising the mount structure for an electrical board according to claim 1.

12. The image forming apparatus according to claim 11, a bottom frame disposed on a lowermost side includes a plate that constitutes an apparatus main body of the image forming apparatus.

13. The image forming apparatus according to claim 12, wherein a circuit board that includes an electronic component for performing drive control of an image forming portion is mounted over the bottom frame.
